(19) United States
(12) Patent Application Publication
(10) Pub. No.: US 2025/0298058 A1
(43) Pub. Date: Sep. 25, 2025

(54) SYSTEM AND METHOD FOR PRECISION CURRENT AND EFFICIENCY DETERMINATION IN A POWER SYSTEM

(71) Applicant: Aivres Systems Inc., San Jose, CA (US)

(72) Inventor: Yiting Chang, New Taipei City (TW)

(21) Appl. No.: 19/230,990

(22) Filed: Jun. 6, 2025

(51) Int. Cl. G01R 15/14; G01R 19/22; G01R 31/42; H02M 1/00

(52) U.S. Cl. CPC G01R 15/146; G01R 19/22; G01R 31/42; H02M 1/0009

(57) ABSTRACT

A system and method for determining current and efficiency are provided. A current measurement circuit includes a plurality of precision current measurement devices. Each of the precision current measurement devices has a respective operating range and is configured to be coupled to a voltage converter via a second input power. A switch circuit includes a plurality of switches. One end of each of the plurality of switches is connected to a respective one of the plurality of precision current measurement devices and an other end of each of the plurality of switches is connected to a first input power. A controller is electrically coupled to the current measurement circuit and the switch circuit. The controller is configured to selectively close the plurality of switches to place a subset of the plurality of precision current measurement devices in an active mode such that each of the subset of the plurality of precision current measurement devices is within the respective operating range and to determine a total current at the second input power.

### TECHNICAL FIELD

This disclosure generally relates to current and efficiency determination of a power system in an electronic device.

### BACKGROUND

Efficiency in the power system of an electronic device, such as a computer system, e.g., server, is an important factor, which affects performance, cost-effectiveness, and user experience. An efficient electronic device can handle more requests and heavier workloads, boosting overall productivity while consuming less power. An efficient electronic device also makes the system more environmentally friendly. For example, by generating less heat during operation, efficient electronic devices reduce the demand for internal and external cooling equipment. Improved thermal management in turn extends the lifespan of the electronic device and enhances overall system reliability. Determining efficiency of an electronic system requires precise measurement of power input and power output, which in turn generally requires precise current measurements.

### SUMMARY

In an exemplary embodiment, a current and efficiency determination circuit includes a current measurement circuit with a plurality of precision current measurement devices. Each of the precision current measurement devices has a respective operating range and is configured to be coupled to a voltage converter via a second input power. A switch circuit includes a plurality of switches. One end of each of the plurality of switches is connected to a respective one of the plurality of precision current measurement devices and an other end of each of the plurality of switches is configured to be connected to a first input power. A controller is electrically coupled to the current measurement circuit and the switch circuit. The controller is configured to selectively close the plurality of switches to place a subset of the plurality of precision current measurement devices in an active mode such that each of the subset of the plurality of precision current measurement devices is within the respective operating range; and determine a total current at the second input power.

In a further exemplary embodiment a power system includes a power supply unit providing a first input power, a voltage converter, a load coupled to the voltage converter via a first output power, and a current and efficiency determination circuit. The current and efficiency determination circuit includes a current measurement circuit with a plurality of precision current measurement devices. Each of the precision current measurement devices has a respective operating range and is configured to be coupled to the voltage converter via a second input power. The current and efficiency determination circuit also includes a switch circuit having a plurality of switches. One end of each of the plurality of switches is connected to a respective one of the plurality of precision current measurement devices, and an other end of each of the plurality of switches is configured to be connected to the first input power. The current and efficiency determination circuit further includes a controller electrically coupled to the current measurement circuit and the switch circuit. The controller is configured to: selectively close the plurality of switches to place a subset of the plurality of precision current measurement devices in an active mode such that each of the subset of the plurality of precision current measurement devices is within the respective operating range; and determine a total current at the second input power.

In another aspect, the controller is further configured to determine an efficiency of the voltage converter.

In another aspect, one or more of the plurality of precision current measurement devices is a shunt resistor.

In another aspect, each of the plurality of precision current measurement devices is a shunt resistor having a same resistance value.

In another aspect, each of the plurality of precision current measurement devices is a shunt resistor, and at least one shunt resistor of the plurality of precision current measurement devices has a different resistance value than another shunt resistor of the plurality of precision current measurement devices.

In another aspect, the switch circuit further includes a bypass switch configured to bypass the current measurement circuit.

In another aspect, the controller selectively closes the plurality switches with a pulse width modulated (PWM) signal.

In another aspect, the current measurement circuit includes at least one voltage measurement device configured to determine a voltage across at least one of the plurality of precision current measurement devices.

In a further exemplary embodiment, a method for precision current measurement of a power system in an electronic device is provided. The electronic device includes a power supply unit, a voltage converter and a current and efficiency determination circuit. The method includes determining an initial current through a first precision current measurement device. The first precision current measurement device is one of a plurality of precision current measurement devices. Each of the precision current measurement devices has a respective operating range. The method also includes determining a subset of the plurality of precision current measurement devices to place in an active mode such that each of the subset of the plurality of precision current measurement devices operates within its respective operating range. The method further includes placing the subset of the plurality of precision current measurement devices in the active mode; and determining a total current flowing through each of the subset of the precision current measurement devices to determine a total current.

In another aspect, the method includes determining an efficiency of the voltage converter.

In another aspect, the method includes bypassing the plurality of precision current measurement devices with a bypass switch.

In another aspect, the method includes selectively closing the plurality switches with a pulse width modulated (PWM) signal.

In another aspect, the method includes determining a voltage across at least one of the plurality of precision current measurement devices with at least one voltage measurement device.

### BRIEF DESCRIPTION OF THE DRAWINGS

FIG. 1 is a block diagram of an electronic device and associated power system with a current and efficiency determination circuit, according to one or more embodiments.

FIG. 2 is a block diagram of an electronic device and associated power system with a first current and efficiency determination circuit and a second current and efficiency determination circuit, according to one or more embodiments.

FIG. 3 is a block diagram of a current and efficiency determination circuit, according to one or more embodiments.

FIG. 4 illustrates a process for determining current and efficiency of an electronic device, according to one or more embodiments.

### DESCRIPTION

The following detailed description is exemplary in nature and is not intended to limit the disclosure or the application and uses of the methods and systems described herein. Furthermore, there is no intention to be bound by any expressed or implied theory presented in the preceding technical field, background, summary and brief description of the drawings, or the following detailed description. Numerous specific details are set forth in order to provide a more thorough understanding of the disclosed technology. However, it will be apparent to one of ordinary skill in the art that the disclosed technology may be practiced without these specific details. In other instances, well-known features have not been described in detail to avoid unnecessarily complicating the description.

Exemplary systems and methods discussed herein provide for precise measurement of input current and power to an electronic component, such as power conversion device, e.g., a voltage conversion device. In certain embodiments, efficiency of the conversion device or other electronic component can also be determined. The systems and methods allow for optimizing power systems used in electronic devices thereby ensuring compliance with relevant standards, minimizing power consumption, reducing environmental load and minimizing generated heat and the need for cooling equipment.

In certain embodiments, the systems and methods include a first current and efficiency determination circuit interposed between an input power device and a converter, such as a voltage converter, e.g., a direct current (DC) to DC converter. The first current and efficiency determination circuit includes a plurality of precision current measurement devices, which can be selectively employed (e.g., placed in an active mode) depending on overall system conditions, such as current, voltage and power. The system and method allow for precise determination of input current and input power to the converter, which can be compared to output power to determine efficiency over different operating conditions. In certain embodiments, these determinations can be used to optimize system performance. In certain embodiments, a second current and efficiency determination circuit can be interposed between an output of the converter and a system load.

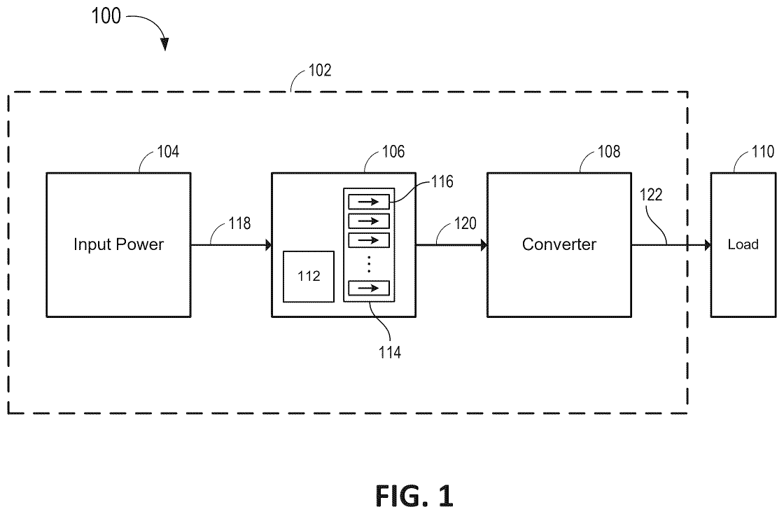

FIG. 1 illustrates a portion of electronic device 100 that includes its power system 102, e.g., power supply unit (PSU). The electronic device 100 may, for example, be a computer system and as a more particular example may be a server. The methods and systems contemplate that the electronic device 100 may also be a laptop, mobile phone, tablet, gaming system or any other electronic device with a power system.

The power system 102 includes an input power circuit 104, which may receive its input power from any suitable source, such as, for example, line voltage, e.g., 120 or 240 Vac. In other embodiments the input power circuit 104 may obtain input power from other sources, such a DC voltage source or low voltage alternating current (AC) source. The input power circuit 104 may in turn convert the input power to one or more first power input sources, which may in certain embodiments include one or more different first input voltages, referred to as first input power 118. By way of example only, the first input voltage may be about 12 V AC/DC. In other embodiments, the first voltage of the first input power 118 may be less than 12 V AC/DC and in yet other embodiments the first voltage of the first input power 118 may be greater than 12 V AC/DC.

Various subsystems and/or components within the system may require varying voltages for operation. For example, 12 Vdc is often used to power central processing units (CPUs), graphic processing units (GPUs), fans, hard drives and peripheral component interconnect express (PCIe) devices; 5 Vdc is often used for universal serial bus (USB) and certain logic circuits; and 3.3 Vdc is often used to power RAM and other logic-level components on a motherboard. In certain implementations −12 Vdc and −5 Vdc are also used. These examples are provided by way of illustration and not limitation.

To facilitate generation of regulated voltage, and in certain embodiments different voltage levels, a converter 108, such as a DC to DC voltage converter may be employed. For example, the converter 108 converts the first input power 118, which is routed to a second input power 120, to a first output voltage, via a first output power 122. The first output voltage may be, for example, one or more of ±12 Vdc., ±5 Vdc, ±3/3 Vdc, etc. The first output power 122 is then connected to load 110, which can be circuitry, e.g., such as found on a motherboard, expansion card, fans, cooling equipment and the like. In certain embodiments, the load 110 may be a simulated load to facilitate current measurement and efficiency determination.

In accordance with certain embodiments, a first current and efficiency determination circuit (also referred to herein as simply current and efficiency determination circuit 106) is electrically coupled to the input power circuit 104 and the converter 108. The first input power 118 is electrically coupled, and serves as an input, to the current and efficiency determination circuit 106. The current and efficiency determination circuit 106 provides as an output, a second input power 120, which is in turn electrically coupled, and serves as input, to the converter 108.

The current and efficiency determination circuit 106 includes a first controller, e.g., controller 112 and a first current measurement circuit, e.g., current measurement circuit 114. The current measurement circuit 114 includes a plurality of first precision current measurement devices, e.g., precision current measurement devices generally labelled 116. Each precision current measurement device 116 may be suitable for measuring current over an operating range, which can be any suitable range. The operating range includes minimum and maximum values, e.g., current levels, voltage levels, etc. over which the respective precision current measurement device can accurately measure current within desired accuracy parameters (e.g., percent error) without exceeding its maximum rating. A non-limiting example of precision current measurement device is a shunt resistor as described below.

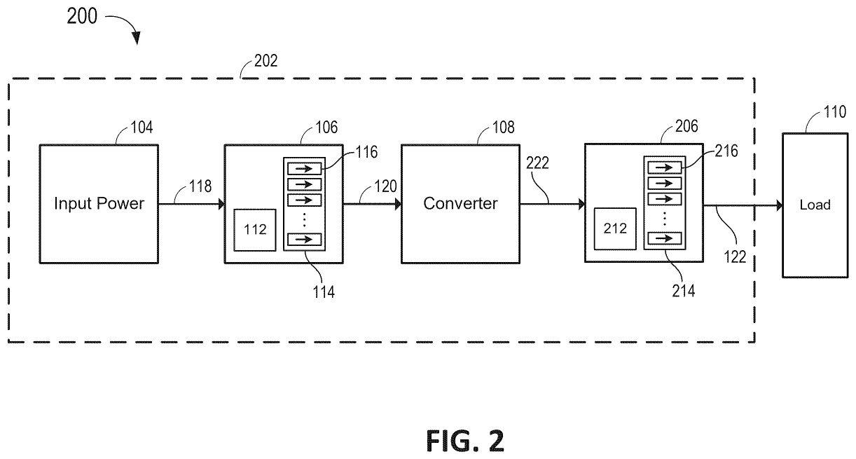

The controller 112 may be any suitable processing system, e.g., microprocessor, microcontroller, application specific integrated circuit (ASIC), discrete circuit or other suitable device for carrying out the methods described herein. As described in connection with FIG. 2, the controller 112 may be communicatively coupled to a memory. The controller 112 selectively controls the current measurement circuit 114 to measure the current and/or power supplied to the converter 108 via the second input power 120.

In accordance with certain embodiments, controller 112 determines whether certain parameters (e.g., current, voltage and/or power) of one or more precision current measurement devices 116 are within their respective operating range, e.g., within the range where the precision current measurement device can accurately measure current within allowable percent error. If the parameters of the particular precision current measurement device 116 are not within the operating range, the controller 112 determines a number and type of precision current measurement devices 116 needed to maintain each within its respective operating range. In some embodiments, the operating range for each of the plurality of precision current measurement devices 116 in the current measurement circuit 114 is the same. In other embodiments, the operating range of a first subset of precision current measurement devices 116 is different from the operating range of at least a second subset of precision current measurement devices 116.

The controller 112 may measure the current over a variety of operating conditions. For example, the controller 112 may measure total current input to the converter 108 where the load 110 is a maximum load. In other embodiments, the controller 112 may measure the total current input to the converter 108 where the load 110 is a minimum load. In yet other implementations, the controller 112 may measure the total current input to the converter 108 where the load 110 is an intermediate load between maximum load and minimum load, such as during normal operating conditions, e.g., eighty (80) percent of maximum load. Of course, these are not exclusive of each other. The controller 112 may measure the current over a variety of operating conditions over time.

The controller 112 may also determine efficiency of the converter 108. Efficiency may be quantified as (Output Power)/(Input Power). Output power is the power delivered to the load 110 by the converter 108, e.g., first output power 122. Input power is power input to the converter 108, e.g., via second input power 120. The input power may be determined by determining the current through the current measurement circuit 114 in conjunction with a second input voltage delivered with the second input power 120. Output power can be determined when the power consumption of the load 110 is known. In alternative embodiments, the output power can be determined from a second current and efficiency determination circuit as described in connection with FIG. 2.

The current and efficiency determination circuit 106 may be a permanent component of the power system 102. In other embodiments, the current and efficiency determination circuit 106 may be only temporarily connected to the power system 102 to measure current and/or determine efficiency.

FIG. 2 illustrates an example of a portion of input device 200 that includes a power system 202, e.g., PSU. The power system 202 of FIG. 2 is similar to the power system 102 described in connection with FIG. 1, but also includes a second current and efficiency determination circuit 206.

The second current and efficiency determination circuit 206 is electrically coupled to the converter 108 and the load 110. In contrast to FIG. 1, the first output power 122 is connected to an output of the second current and efficiency determination circuit 206 and to the load 110. A second output power 222 is electrically coupled to the output of the converter 108 and to an input of the second current and efficiency determination circuit 206.

The second current and efficiency determination circuit 206 is similar in structure and operation to the current and efficiency determination circuit 106. In particular, the second current and efficiency determination circuit 206 includes second controller 212 and a second precision current measurement circuit 214. The second precision current measurement circuit 214 includes a plurality of second precision current measurement devices 216. Like the current and precision current measurement devices 116, each second precision current measurement device 216 may have an associated operating range, which can be any suitable range. The second precision current measurement devices 216 may be any suitable circuit components for precision measurement of current, e.g., shunt resistors.

Similar to the current and efficiency determination circuit 106, the second current and efficiency determination circuit 206 determines whether parameters of the second precision current measurement device(s) 216 is/are within an appropriate operating range where the operating range may be function of power, current, voltage and the like. If the parameters of the second precision current measurement device(s) 216 is/are not within an appropriate operating range, the second controller 212 determines a number and type of second precision current measurement devices 216 needed to achieve an appropriate operating range for each second precision current measurement device. The appropriate operating range for each of the plurality of second precision current measurement devices 216 in the second precision current measurement circuit 214 may be the same. In other embodiments, a first subset of second precision current measurement devices 216 may have a different operating range than at least a second subset of the second precision current measurement devices 216.

In the embodiment of FIG. 2, the power consumption characteristics of the load 110 need not be known. The second current and efficiency determination circuit 206 can measure the current actually delivered to the load 110 for a given voltage via the first output power 122.

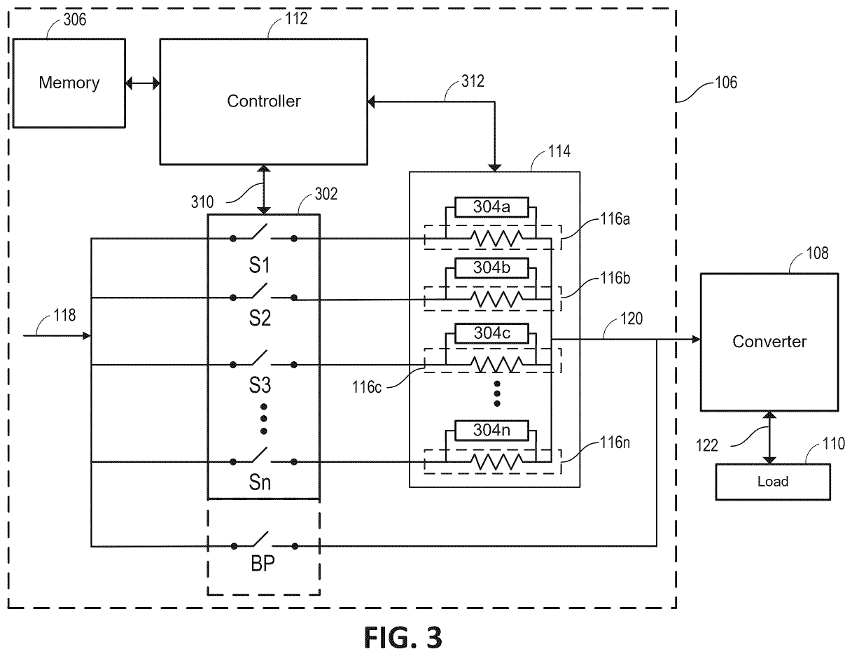

FIG. 3 illustrates an embodiment of a current and efficiency determination circuit, e.g., current and efficiency determination circuit 106 as described in connection with FIG. 1. The current and efficiency determination circuit 106 includes the controller 112 and the current measurement circuit 114. It will be appreciated that the description which follows also applies to the second current and efficiency determination circuit 206 and associated components described in connection with FIG. 2, except where otherwise apparent.

Also shown are the converter 108 and the load 110, which are connected via the second input power 120 and the first output power 122 as previously described.

In certain embodiments, the controller 112 is coupled to memory 306. The memory 306 may be volatile or non-volatile memory, e.g., random access memory (RAM), read only memory (ROM), electrically erasable memory (EEPROM), solid state drive, and/or other suitable memory. In some implementations, the memory 306 may be integral to the controller 112. In other implementations, the memory be separate from the controller 112. The memory 306 may store computer readable instructions for carrying out operations of the controller 112. The memory may also store data obtained by the current and efficiency determination circuit 106, such as measured or calculated current, power and efficiency measurements.

The current measurement circuit 114 includes a plurality of first precision current measurement devices labelled 116a through 116n, where n is a positive integer greater than one. In the particular example shown, the precision current measurement devices 116a through 116n are shown as resistors. The resistors may, for example, be precision shunt resistors with a known resistance value. The precision shunt resistors typically have a low but precise resistance value such that they have only a small effect on the value of the current therethrough. By way of example, suitable shunt resistors may have values in the range of microohms (μΩ) to milliohms (mΩ). As specific examples, the shunt resistors may be in the range of about 100 μΩ to 100 mΩ; however, in some embodiments the shunt resistors may have a value of less than 100 μΩ or more than 100 mΩ. Operating currents through the resistors may be less than 1 ampere (A) to 50 A or more. When used as the precision current measurement devices, the shunt resistors may all have a same resistance value or one or more shunt resistors may have a different resistance value than other shunt resistors.

In certain embodiments, the current measurement circuit 114 also includes one or more voltage measurement devices 304a through 304n coupled to one or more of the plurality of precision current measurement devices 116a through 116n. In certain embodiments, only one or less than all of the precision current measurement devices 116a through 116n have a corresponding voltage measurement device 304a through 304n. For example, precision current measurement device 116a may have a corresponding voltage measurement device 304a. Precision current measurement devices 116b through 116n may not have a corresponding voltage measurement device 304b through 304n. In other embodiments, more than one or all of the precision current measurement devices 116a through 116n have a corresponding voltage measurement device 304a through 304n.

Each voltage measurement device 304a through 304n is configured to measure the voltage across the corresponding precision current measurement device 116a through 116n, e.g., shunt resistor. The voltage measurement devices 304a through 304n may be any suitable device configured to convert measured voltage to a digital or analog signal that is communicated to the controller 112 via a power measurement signal 312. An example of a voltage measurement device 304a through 304n is an analog to digital converter configured to convert a voltage value to a digital signal. In other embodiments, voltage measurement devices 304a through 304n are omitted and measurement of the voltage across the precision current measurement devices is directly read and determined by the controller 112.

As previously described, each precision current measure device 116a through 116n may provide for precision current measurement (e.g., within desired level of accuracy) over an operating range. The operating range depends on a variety of factors. In the case of a shunt resistor, one factor is the maximum power rating of the shunt resistor, e.g. maximum watts (W). Pₘₐₓ=I²ₘₐₓ×Rₛₕᵤₙₜ, where Iₘₐₓ is the maximum current and Rₛₕᵤₙₜ is resistance of the shunt resistor. Each shunt resistor should operate such that its power rating will not be exceeded when the maximum current flow through it is reached. Further, a large voltage drop across the resistor will naturally adversely affect circuit performance. Thus, each shunt resistor should operate so that the measured voltage drop does not exceed a maximum voltage drop, e.g., V_{measured}<Vₘₐₓ. By way of example, Vₘₐₓ may be in the range of 50 mV to 200 mV although these values may vary depending on the load. Additionally, each shunt resistor should operate so that the measured voltage drop is greater than a minimum voltage, e.g., (V_{measured}>Vₘᵢₙ), to ensure measured current is within the desired level of accuracy, e.g., current measured accurate to within a fraction of one percent to one percent. Vₘᵢₙ will vary depending on specifications of the voltage measurement devices 304a through 304n (when used) and/or controller.

Switch circuit 302 includes a plurality of switches generally labelled S1 through Sn, where n is an integer greater than one. The number of switches 304 may at least equal the number of precision current measurement devices 116a through 116n. The switches may be electronic switches, e.g., transistors such as MOSFETs, Power Field Effect Transistors (Power FETs), etc. or any other suitable electronic switch. Alternatively, the switches may be relays or other suitable electromechanical devices. In certain embodiments, the switch circuit 302 may include logic for opening and closing the switches responsive to signals from the controller 112.

As generally shown, one end of each switch S1 is connected to input power, e.g., first input power 118, while the other end of each switch is connected to an input end of a respective one of the precision current measurement devices 116a through 116n. The other end of each precision current measurement device 116a through 116n is connected to the second input power 120 of the converter 108. Thus, the switch circuit 302 allows selectively placing any one or more of the precision current measurement devices 116a through 116n in line with the current to the converter 108. When a switch corresponding to a precision current measurement device 116a through 116n is closed, the corresponding precision current measurement device 116a through 116n is referred to as active or being in an active mode. Conversely, when a switch corresponding to a precision current measurement device 116a through 116n is open, the corresponding precision current measurement device 116a through 116n is referred to as inactive or being in an inactive mode.

In the particular embodiment shown, when a plurality of the switches S1 through Sn are closed, the corresponding precision current measurement devices 116a through 116n that are active (subset of current measurement devices in the active mode) are connected in parallel. It will be appreciated that other configurations may be employed.

In certain embodiments, the switch circuit 302 may also include a bypass switch BP. By opening the switches S1 through Sn, e.g., placing precision current measurement devices 116a through 116n in an inactive mode, and closing the bypass switch 308, the current measurement circuit 114 can be bypassed. Such operation may be appropriate, for example, when current and efficiency measurement and determination are not needed, e.g., referred to bypass mode.

The controller 112 controls operating the switches S1 through Sn via a power measurement signal 312. Any suitable signaling may be employed. For example, the controller 112 may use a pule width modulated (PWM) signal to operate the switching mechanism. The pulse width may identify which switches S1 through Sn to open (or close) and when applicable whether to open (or close) the bypass switch (BP). For example, a short pulse may signal to close (or open) switch S1 with consecutively longer pulses signaling to close (or open) switches S2, S3 through Sn, respectively. No pulse may signal to close the bypass switch BP and open switches S1 through Sn to place the device in bypass mode. Alternatively, the controller 112 may directly operate each of the switches S1 through Sn without using a PWM signal.

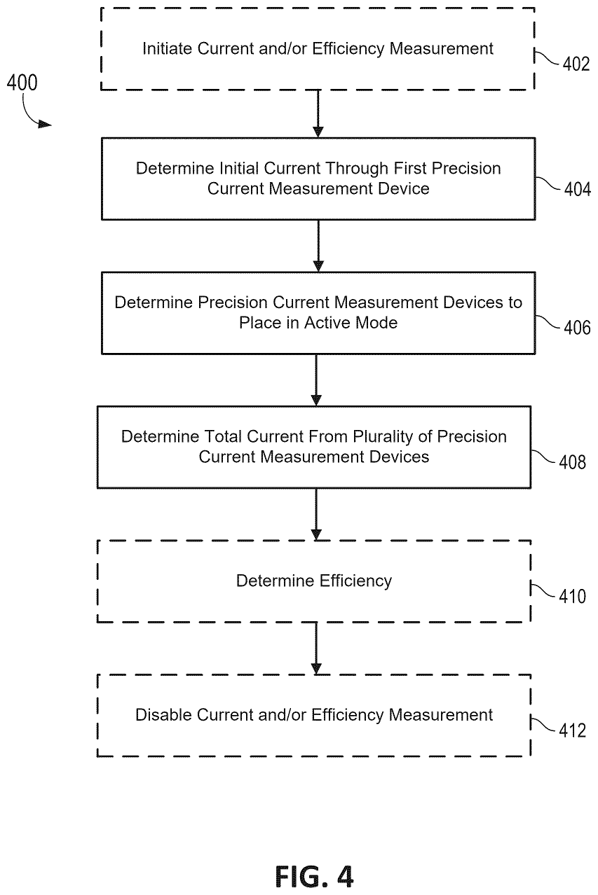

FIG. 4 illustrates a method 400 of precise current measurement and/or efficiency determination according to embodiments described herein. It will be understood that the method is described by way of illustration and not limitation. The method 400 need not performed in the order shown except where otherwise apparent from the context. Further, certain stages are optional as will be apparent from the description which follows. As a specific example, stages 402, 410, and 412 shown with dashed lines are optional.

In stage 402, the system, e.g., controller 112, initiates current and/or efficiency measurement. The current and/or efficiency measurement may be initiated by, for example, opening bypass switch BP (when present) as shown in described in FIG. 3. At least one switch S1 through Sn is closed placing corresponding precision current measuring devices in an active mode with any remaining switches open. As but one example, with reference to FIG. 3, switch S1 is closed thereby placing precision current measuring device 116a in an active mode and switches S2 through Sn are open thereby placing precision current measuring devices 116b through 116n in an inactive mode. As another example, all switches S1 through Sn are closed thereby placing precision current measuring devices 116a through 116n in an active mode. The configuration of open and closed switches is effectuated via switch control signal 310, which as previously described may be a PWM signal.

In stage 404, the controller 112 determines the initial parameters (e.g., voltage, current and/or power) of the initial set of precision current measurement devices in the active mode.

As one illustrative example, assuming switch S1 is closed and the remaining switches S2 through Sn are open, the voltage across the precision current measurement device 116a, e.g., shunt resister, is measured using voltage determination device 304a. The voltage is communicated to the controller 112 through power measurement signal 312. The controller determines the current and power of the precision current measurement device 116a, e.g., I₃₀₄ₐ=R₃₀₄ₐ/V₃₀₄ₐ and P₃₀₄ₐ=V₃₀₄ₐ×I₃₀₄ₐ where V₃₀₄ₐ is the voltage measured across precision current measurement device 116a and R₃₀₄ₐ is the known resistance of precision current measurement device 166a.

As another illustrative example, assuming switches S1 through Sn are closed thereby placing all precision current measurement devices 116a through 116n in the active mode, the voltage across each of the precision current measurement devices 116a through 116n are measured using voltage determination device 304a (or alternatively separately by voltage determination devices 304a through 304n). The voltage is communicated to the controller 112 through power measurement signal 312. The current and power of each of the precision current measurement devices 116a through 116n is then determined, e.g., I₃₀₄ᵢ=R₃₀₄ᵢ/V₃₀₄ᵢ and P₃₀₄ᵢ=V₃₀₄ᵢ×I₃₀₄ᵢ where V₃₀₄ᵢ is the voltage measured across the precision current measurement devices, R₃₀₄ᵢ is the known resistance of precision current measurement device 166a through 116n and i corresponds to the precision current measurement device 1 through n.

In stage 406, the controller 112 determines a subset (e.g., which and how many) precision current measurement devices 116a to 116n to put in an active mode so that power, voltage and current of each precision current measurement device in the active mode is within its operating range to facilitate precise measurement of current. The subset may include one, all or any number in between of the precision measurement devices. For example, in the case where switch S1 is closed and switches S2 through Sn are open during the initial determination of parameters (stage 404), the controller determines if the current, voltage, and power of the precision current measurement device 116a is within its operating range. As previously described, the operating range is a range such that the maximum power (Pₘₐₓ) of the shunt is not exceeded, the measured voltage across the shunt resistor does not exceed a maximum voltage (Vₘₐₓ) and the measured voltage across the shunt resistor exceeds the minimum voltage (Vₘᵢₙ) needed for accurate measurement of the current, e.g., ±0.1 to 1 percent.

If the controller 112 determines the initial parameters are outside the operating range of precision current measurement device(s) 116a-116n in the active mode, the controller closes (or opens) an appropriate number of switches to place a subset of precision current measuring devices in an active mode such that each precision current measuring device in the subset is within its operating range.

In stage 408, a precise current measurement is obtained by determining the total current as a sum of each of the currents flowing the subset of the precision current measurement devices in the active mode following stage 406. In the example of FIG. 2, the current through each precision current measurement device can be determined by measuring the voltage drop across the shunt resistor(s) using voltage measurement device 304a or alternatively, voltage measurement devices 304a through 304n corresponding to each precision current measurement device 116a through 116n in the active mode. The current can then be determined from the voltage (V) and resistance (R) by V/R where R is the resistance of each shunt resistor of the subset of precision current measurement devices in the active mode. In some embodiments, only one voltage measurement need be taken where, for example, the resistors are in parallel as shown in FIG. 2. In other embodiments, the voltage across each shunt resistor in the active mode may be taken separately.

In stage 410, in certain embodiments, efficiency of a device, e.g., the converter 108, may also be ascertained by the controller 112. The input power to the converter 108 is the power input at the second input power 120, e.g., the current determined in stage 408 times the voltage delivered to the converter. The output power can be ascertained where the power consumption of the load 110 is known. In other embodiments, as described in connection with FIG. 2, a second current and efficiency determination circuit 206 can be interposed between the converter 108 and the load 110. Stages 402 through 408 can be performed concurrently or consecutively on second current and efficiency determination circuit 206 to determine the output power of the converter 108. The efficiency may then be determined by dividing the output power by the input power.

In stage 412, current and/or efficiency measurement can be disabled, by for example, opening all switches S1 through Sn and closing switch BP thereby placing the power system in bypass mode.

It will be appreciated that the controller 112 can maintain statistics of efficiency over varying load conditions. The controller 112 may disable certain system components when not in use to maintain more efficient power delivery to the system. The controller 112 can also provide a signal to the system when, for example, the efficiency of one or more converters drops below a benchmark value. In such cases, the inefficient converter, or even the entire power system, can be replaced to achieve more efficient operation.

In view of the foregoing, it will be appreciated that exemplary embodiments of the present disclosure to determine input current to a converter with precision. Efficiency can be determined by using a known load and/or second current and efficiency determination circuit according to the methods and systems described therein. Inefficient systems can have appropriate portions of the power systems replaced or can be configured to operate efficiently by, for example, disabling unnecessary system operations during certain modes to achieve efficient operation.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the embodiments (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate the embodiments and does not pose a limitation on the scope of the embodiments unless otherwise claimed. No language in the specification should be construed as indicating any non-claimed element as essential to the practice of the embodiments.

Exemplary embodiments are described herein. Variations of those exemplary embodiments may become apparent to those of ordinary skill in the art upon reading the foregoing description. The inventors expect skilled artisans to employ such variations as appropriate, and the inventors intend for the embodiments to be practiced otherwise than as specifically described herein. Accordingly, these embodiments includes all modifications and equivalents of the subject matter recited in the claims appended hereto as permitted by applicable law. Moreover, any combination of the above-described elements in all possible variations thereof is encompassed by the embodiments unless otherwise indicated herein or otherwise clearly contradicted by context.

1. A current and efficiency determination circuit, comprising:
a current measurement circuit comprising a plurality of precision current measurement devices, wherein each of the precision current measurement devices has a respective operating range and wherein each of the precision current measurement devices is configured to be coupled to a voltage converter via a second input power;
a switch circuit comprising a plurality of switches, wherein one end of each of the plurality of switches is connected to a respective one of the plurality of precision current measurement devices, and wherein an other end of each of the plurality of switches is configured to be connected to a first input power; and
a controller electrically coupled to the current measurement circuit and the switch circuit, wherein the controller is configured to:
selectively close the plurality of switches to place a subset of the plurality of precision current measurement devices in an active mode such that each of the subset of the plurality of precision current measurement devices is within the respective operating range; and
determine a total current at the second input power.

2. The current and efficiency determination circuit of claim 1, wherein the controller is further configured to determine an efficiency of the voltage converter.

3. The current and efficiency determination circuit of claim 1, wherein one or more of the plurality of precision current measurement devices is a shunt resistor.

4. The current and efficiency determination circuit of claim 1, wherein each of the plurality of precision current measurement devices is a shunt resistor having a same resistance value.

5. The current and efficiency determination circuit of claim 1, wherein each of the plurality of precision current measurement devices is a shunt resistor, and wherein at least one shunt resistor of the plurality of precision current measurement devices has a different resistance value than another shunt resistor of the plurality of precision current measurement devices.

6. The current and efficiency determination circuit of claim 1, wherein the switch circuit further comprises a bypass switch configured to bypass the current measurement circuit.

7. The current and efficiency determination circuit of claim 1, wherein the controller selectively closes the plurality switches with a pulse width modulated (PWM) signal.

8. The current and efficiency determination circuit of claim 1, wherein the current measurement circuit comprises at least one voltage measurement device configured to determine a voltage across at least one of the plurality of precision current measurement devices.

9. A power system comprising:
a power supply unit providing a first input power;
a voltage converter;
a load coupled to the voltage converter via a first output power;
a current and efficiency determination circuit, comprising:
a current measurement circuit comprising a plurality of precision current measurement devices wherein each of the precision current measurement devices has a respective operating range and wherein each of the precision current measurement devices is configured to be coupled to the voltage converter via a second input power;
a switch circuit comprising a plurality of switches, wherein one end of each of the plurality of switches is connected to a respective one of the plurality of precision current measurement devices, and wherein an other end of each of the plurality of switches is configured to be connected to the first input power;
a controller electrically coupled to the current measurement circuit and the switch circuit, wherein the controller is configured to:
selectively close the plurality of switches to place a subset of the plurality of precision current measurement devices in an active mode such that each of the subset of the plurality of precision current measurement devices is within the respective operating range; and
determine a total current at the second input power.

10. The power system of claim 9, wherein the controller is further configured to determine an efficiency of the voltage converter.

11. The power system of claim 9, wherein one or more of the plurality of precision current measurement devices is a shunt resistor.

12. The power system of claim 9, wherein each of the plurality of precision current measurement devices is a shunt resistor, and wherein at least one shunt resistor of the plurality of precision current measurement devices has a different resistance value than another shunt resistor of the plurality of precision current measurement devices.

13. The power system of claim 9, wherein the switch circuit further comprises a bypass switch configured to bypass the current measurement circuit.

14. The power system of claim 9, wherein the controller selectively closes the plurality switches with a pulse width modulated (PWM) signal.

15. The power system of claim 9, wherein the current measurement circuit comprises at least one voltage measurement device configured to determine a voltage across at least one of the plurality of precision current measurement devices.

16. A method for precision current measurement of a power system in an electronic device, the electronic device comprising a power supply unit, a voltage converter, a current and efficiency determination circuit, and a controller, the method comprising:
determining, by the controller, an initial current through a first precision current measurement device, wherein the first precision current measurement device is one of a plurality of precision current measurement devices, and wherein each of the precision current measurement devices has a respective operating range;
determining, by the controller, a subset of the plurality of precision current measurement devices to place in an active mode such that each of the subset of the plurality of precision current measurement devices operates within its respective operating range;
placing, by the controller, the subset of the plurality of precision current measurement devices in the active mode; and
determining, by the controller, a total current flowing through each of the subset of the precision current measurement devices to determine a total current.

17. The method of claim 16, further comprising:
determining an efficiency of the voltage converter.

18. The method of claim 16, further comprising:
bypassing the plurality of precision current measurement devices with a bypass switch.

19. The method of claim 16, further comprising:
selectively closing a plurality switches with a pulse width modulated (PWM) signal to place the subset of the plurality of precision current measurement devices in the active mode.

20. The method of claim 16, further comprising:
determining a voltage across at least one of the plurality of precision current measurement devices with at least one voltage measurement device.
